(19) United States
(12) Patent Application Publication
(10) Pub. No.: US 2008/0175089 A1
(43) Pub. Date: Jul. 24, 2008

(54) FLASH MEMORY CARD

(76) Inventors: Seok-Won Heo, Seoul (KR); Chang-Duck Lee, Seoul (KR); Jae-Sung Yu, Seoul (KR); Dong-Ryoul Lee, Incheon (KR)

Correspondence Address: F. CHAU & ASSOCIATES, LLC, 130 WOODBURY ROAD, WOODBURY, NY, 11797, US

(21) Appl. No.: 11/695,267

(22) Filed: Apr. 2, 2007

(30) Foreign Application Priority Data
Jan. 19, 2007 (KR) 2007-06097

(51) Int. Cl. G11C 8/12

(52) U.S. Cl. 365/230.03

(57) ABSTRACT

A flash memory card including a main memory core, a removable supplementary memory core, and a controller operating to control the main and supplementary memory cores. The supplementary memory core includes a plurality of memory cores and is replaceable.

### CROSS-REFERENCE TO RELATED APPLICATION

This application claims priority under 35 U.S.C. § 119 of Korean Patent Application No. 2007-06097 filed on Jan. 19, 2007, the entire contents of which are hereby incorporated by reference.

### BACKGROUND

The present disclosure relates to flash memory cards and, more particularly, to a flash memory card capable of including a main memory core and replacing a supplementary memory core therewith.

A flash memory card (hereinafter, referred to as ‘memory card’) generally includes a memory core and a controller operating to control the overall functionality of the memory card. The controller stores externally input data into the memory core in response to a read/write command provided externally, and transfers data from the memory core to an external device.

While a conventional memory card includes a main memory core, such a main memory core is unable to be separated from the memory card or replaced with a new memory core. Thus, there have been developed memory cards that are able to replace the memory core. A memory card having a replaceable memory core is able to make an internal connection or disconnection with the memory core both electrically and mechanically. A memory card with a replaceable memory core is disclosed in U.S. Pat. No. 6,381,662 entitled ‘REMOVABLE MOTHER/DAUGHTER PERIPHERAL CARD’. If a memory core is removed from such a memory card, however, there is a problem of being incapable of conducting reading/writing operations, because the memory card does not include the memory core.

### SUMMARY OF THE INVENTION

Exemplary embodiments of the present invention are directed to solve the aforementioned problems, providing a flash memory card able to enhance operational efficiency.

Exemplary embodiments of the present invention are also directed to a flash memory card that can be conveniently replaced with a supplementary memory core.

An exemplary embodiment of the present invention is a flash memory card comprised of: a main memory core; a supplementary memory core; and a controller operating to control the main and supplementary memory cores. The supplementary memory core includes pluralities of memory cores and is replaceable.

In this exemplary embodiment, the plurality of memory cores are the same as, or different from, each other in regard to density.

In this exemplary embodiment, when the supplementary memory core is removed from the flash memory card, the controller activates the main memory core.

According to this exemplary embodiment, when the supplementary memory core is connected to the flash memory card, the controller activates the main and supplemental memory cores.

In an exemplary embodiment, the controller includes: a ROM storing firmware to manage the main memory core and the plurality of memory cores in correspondence with respective densities of the main memory core and the plurality of memory cores; a RAM storing firmware to manage the memory core having a density corresponding to firmware that is absent in the ROM; and a central processing unit managing the main memory core and the plurality of memory cores by means of the firmware stored in the ROM and the RAM.

In this exemplary embodiment, the RAM is a static RAM.

According to an exemplary embodiment, the central processing unit reads card identification information of the main memory core and confirms a density of the main memory core from the read card identification information.

In an exemplary embodiment, the central processing unit selects firmware from the ROM in correspondence with the density of the main memory core.

In an exemplary embodiment, the central processing unit controls the main memory core by means of the selected firmware.

According to an exemplary embodiment, the central processing unit reads card identification information of the plurality of memory cores and confirms the density of the plural memory cores by means of the read card identification information.

In an exemplary embodiment, a central processing unit selects the firmware stored in the ROM in correspondence with the densities of each of the plurality of memory cores.

In this exemplary embodiment, the central processing unit controls the plurality of memory cores correspondingly by means of the selected firmware.

According to an exemplary embodiment, if firmware for managing one or more memory cores is absent from the ROM, the central processing unit reads the firmware from memory cores having a density correspondent with the firmware that is absent in the ROM.

In this exemplary embodiment, the central processing unit stores the read firmware into the RAM.

In an exemplary embodiment, the central processing unit selects the firmware stored in the RAM and controls corresponding memory cores by means of the selected firmware.

A further understanding of the nature and advantages of exemplary embodiments of the present invention may be realized by reference to the remaining portions of the specification and the attached drawings.

### BRIEF DESCRIPTION OF THE FIGURES

Exemplary embodiments of the present invention will be understood in more detail from the following description taken in conjunction with the following figures, wherein like reference numerals refer to like parts throughout the various figures unless otherwise specified. In the figures:

FIG. 1 is a block diagram of a flash memory card in accordance with an exemplary embodiment of the present invention;

FIG. 2 is a block diagram illustrating an organization without a memory core in the flash memory card shown in FIG. 1; and

FIG. 3 is a block diagram illustrating an organization with a memory core in the flash memory card shown in FIG. 1.

### DETAILED DESCRIPTION OF EXEMPLARY EMBODIMENTS

Exemplary embodiments of the present invention will be described below in more detail with reference to the accompanying drawings. The present invention may, however, be embodied in different forms and should not be construed as limited to the exemplary embodiments set forth herein. Rather, these exemplary embodiments are provided so that this disclosure will be thorough and complete, and will fully convey the scope of the present invention to those of ordinary skill in the art. Like reference numerals refer to like elements throughout the accompanying figures.

A flash memory card of an exemplary embodiment of the present invention includes a main memory core that is non-replaceable, and a supplementary memory core that is replaceable. Therefore, the flash memory card is able to operate by the main memory core even though the supplementary memory core has been removed therefrom, so that it is high in operational efficiency. Moreover, as the flash memory card is able to add a memory core therein, it is convenient to replace the memory core.

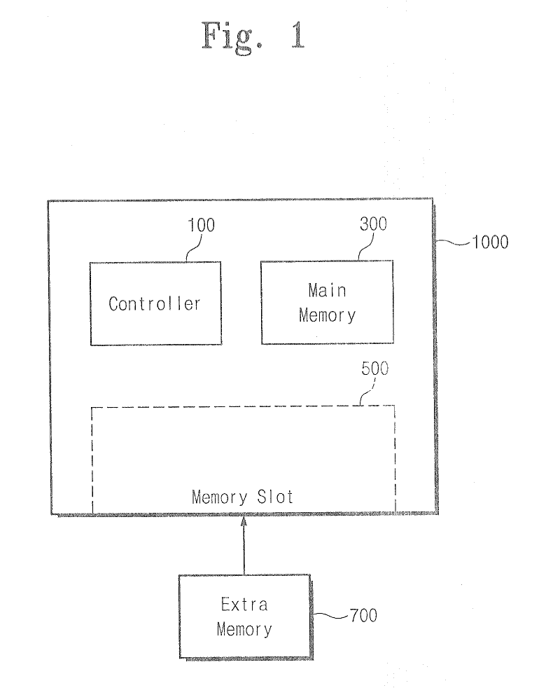

FIG. 1 is a block diagram of a flash memory card in accordance with an exemplary embodiment of the present invention.

Referring to FIG. 1, the flash memory card 1000 (hereinafter referred to as ‘memory card’) is comprised of a controller 100, a main memory core 300 (hereinafter referred to as ‘main memory’), and a memory slot 500. The controller 100 stores firmware and manages the overall operation of the memory card 1000 by means of the stored firmware. The firmware is a kind of micro-program stored in a read-only memory (ROM) of the controller 100 and used for controlling hardware. The ROM stores the firmware for managing the main memory 300, and the firmware for managing a supplementary memory 700 to be added through use of the memory slot 500.

The extra memory 700 (hereinafter referred to as ‘supplementary memory’) is inserted into the memory slot 500. When the supplementary memory 700 is inserted into the memory slot 500, it is electrically and mechanically connected to the memory card 1000. The memories 300 and 700 are NAND flash memories well known in this art.

The main memory 300 is included in the basic memory card 1000 and is not intended to be replaced. Thus, during a normal operation of the memory card 1000, the controller 100 stores externally input data into the main memory 300, or transfers data to an external system from the main memory 300, in response to a command provided from the external system.

In this exemplary embodiment, it is possible to add a memory core in the memory card 1000 as follows. A user inserts the supplementary or extra memory 700 into the memory slot 500. The supplementary or extra memory 700 is connected electrically and mechanically to the memory card 1000 through the memory slot 500. The extra memory 700 contains card identification (ID) information. The controller 100 reads card ID information of the extra memory 700 connected through the memory slot 500, and selects firmware for managing the extra memory 700 in response to the card ID information that has been read out.

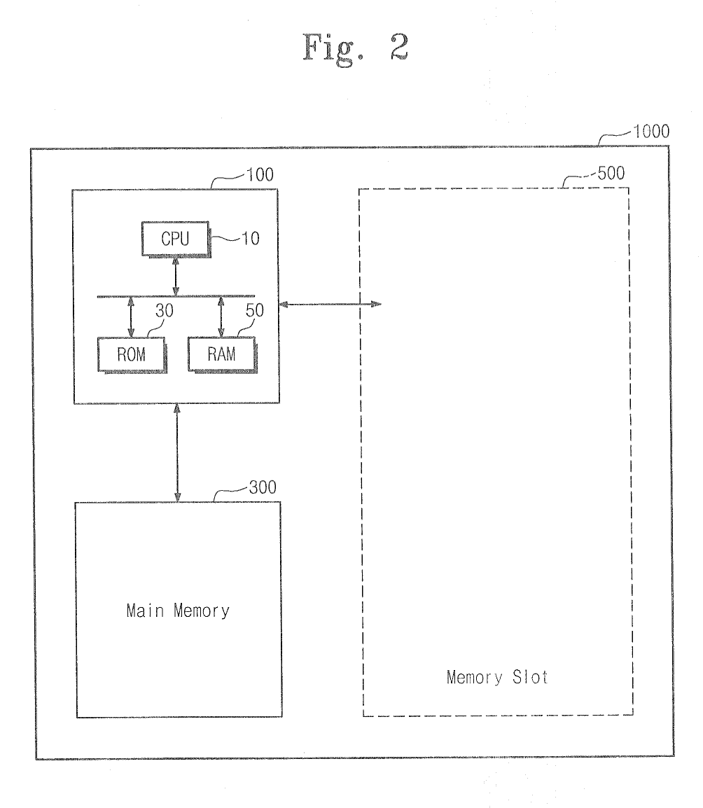

FIG. 2 is a block diagram illustrating an organization of the flash memory card shown in FIG. 1 without the extra memory.

Referring to FIG. 2, the memory card 1000 according to an exemplary embodiment of the present invention is comprised of the controller 100, the main memory 300, and the memory slot 500. The controller 100 includes a central processing unit (CPU) 10, a read only memory (ROM) 30, and a random access memory (RAM) 50. The ROM 30 stores the firmware for controlling the main memory 300, and the firmware for controlling the supplementary memory 700 (not shown in FIG. 2) to be added through the memory slot 500.

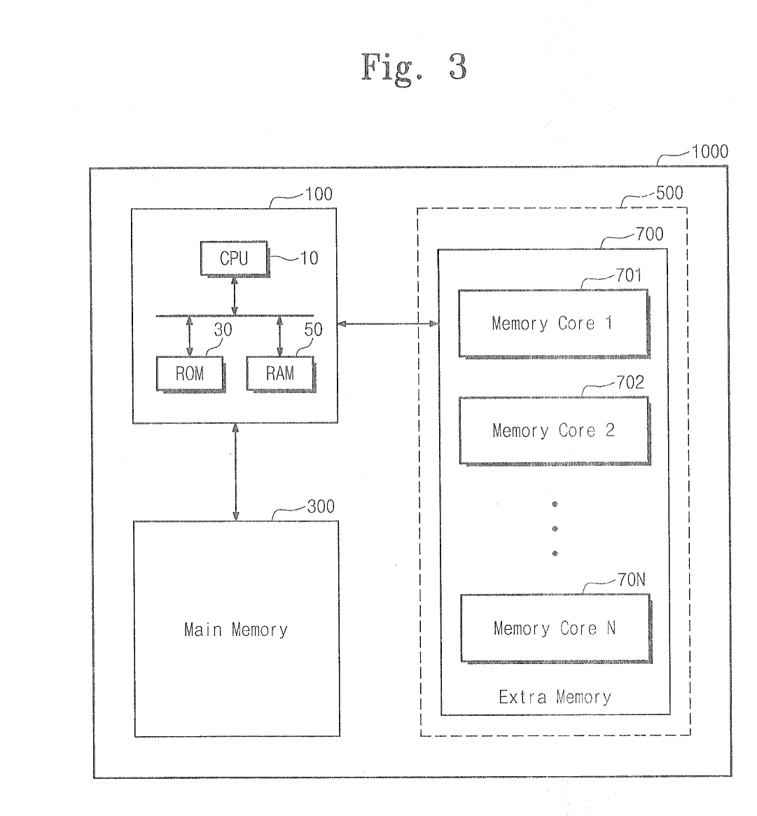

The CPU 10 manages the overall operation of the memory card 1000 by means of the firmware stored in the ROM 30. Thus, the CPU 10 uses the firmware stored in the ROM 30, and manages the main memory 300 and the extra memory 700 to be added through the memory slot 500. The CPU 10, if the ROM 30 does not have firmware for managing the supplementary or extra memory 700, reads firmware, which is absent in the ROM 30, from the supplementary memory 700. Then, the CPU 10 store the read-out firmware into the RAM 50, which will be described in detail with reference to FIG. 3.

If the extra memory 700 is disconnected from memory slot 500 of the memory card 1000, the controller 100 of the memory card 1000 provides the main memory 300 with a control signal (flash chip enable signal) FCEB for identifying the main memory 300. The main memory 300 is then activated in response to the control signal FCEB input thereto. During this time, the CPU 10 of the controller 100 reads card ID information from the main memory 300 that is now active, and then confirms the density of the main memory 300 from the read card ID information. The CPU 10, upon confirming the density of the main memory 300, selects firmware from the ROM 30 in correspondence with the density of the main memory 300 and manages the main memory 300 by means of the selected firmware.

Therefore, unless the extra memory 700 is inserted in the memory slot 500, the memory card 1000 stores externally input data into the main memory 300, and transfers data to an external system (not shown) from the main memory 300, in response to a command provided from the external system.

FIG. 3 is a block diagram illustrating an organization of a memory core in the flash memory card shown in FIG. 1.

Referring to FIG. 3, the memory card 1000 includes the extra memory 700 connected through the memory slot 500. The extra memory 700 includes a plurality of memory cores 701˜70N. The memory cores 701˜70N are the same as or different from each other. Because the configuration of the memory card 1000 is the same as that shown in FIG. 2, it will not be described again. If the extra memory 700 has been connected electrically and physically to the memory card 1000 through the memory slot 500, the controller 100 activates and manages the main memory 300 and the extra memory 700. An operation of the memory card 1000, activating and managing the main memory 300 by way of the controller 100, is as aforementioned, so it will not be described further.

If the extra memory 700 has been connected electrically and physically to the memory card 1000 through the memory slot 500, the controller 100 outputs the control signal FCEB for activating the memory cores 701˜70N of the extra 700. The control signal FCEB output from the controller 100 is provided to the memory cores 701˜70N.

The memory cores 701˜70N of the extra memory 700 are activated in response to the control signal FCEB input from the controller 100. During this time, the CPU 10 of the controller 100 reads card ID information from the activated memory cores 701˜70N, and confirms the densities of the memory cores 701˜70N through the read card ID information. The CPU 10, upon confirming the densities of the memory cores 701˜70N, selects the appropriate firmware from the ROM 30 in correspondence with the densities of the memory cores 701˜70N, and manages the memory cores 701˜70N by means of the selected firmware.

For instance, the ROM 30 of the controller 100 stores the firmware for managing a memory core of 2 Kbytes and a memory core of 4 Kbytes. The density of the cores 701˜70N of the extra memory 700 connected through the memory slot 500 is one of 2 Kbytes and 4 Kbytes. The controller 100 activates the memory cores 701˜70N. During this time, the CPU 10 of the controller 100 reads the card ID information from the activated memory cores 701˜70N, and then confirms the density of the memory cores 701˜70N. If the confirmed memory core density is 2 Kbytes, the CPU 10 selects the firmware in correspondence with the 2-Kbyte density stored in the ROM 30. Thus, the CPU 10 manages the memory cores, which have the 2-Kbyte density, by means of the selected firmware. If the confirmed memory core density is 4 Kbytes, the CPU 10 selects the firmware in correspondence with the 4-Kbyte density stored in the ROM 30. Thus, the CPU 10 manages the memory cores, which have the 4-Kbyte density, by means of the selected firmware.

The CPU 10 of the memory card 100 reads the firmware from the memory core if there is no firmware corresponding to the confirmed memory core density obtained by reading out the card ID information. The firmware read from the memory cores is stored in the RAM 50. The RAM 50 is organized as a static RAM that is well known in this art.

As an example, a density of the memory cores 701˜70N of the extra memory 700 is one of 2 Kbtyes, 4 Kbytes, and 8 Kbytes, and a density of the main memory 300 is 2 Kbytes. The ROM 30 of the controller 100 stores firmware for managing a 2-Kbyte memory core and a 4-Kbyte memory core. If the density of the memory cores 701˜70N is 2 or 4 Kbytes, the controller selects firmware corresponding to each density as aforementioned. On the other hand, the firmware for managing a memory core with an 8-Kbyte density is not stored in the ROM 30 of the controller 100. Generally, a memory core of the extra memory 700 includes firmware. Therefore, unless the firmware for managing a memory core that has the 8-Kbyte density is stored in the ROM 30 of the controller 100, the CPU 10 reads the firmware from the memory core of 8-Kbyte density and stores the read firmware into the RAM 50. The CPU 10 then selects the firmware stored in the RAM 50 in order to manage the memory core having the 8-Kbyte density. Thus, the CPU 100 manages memory cores of 8-Kbyte density by means of the firmware stored in the RAM 50.

As a result, the memory card according to an exemplary embodiment of the present invention includes a main memory core, which is not replaced, that is capable of adding a supplementary memory core. Thus, since the memory card system is able to operate by the main memory core even if the supplementary memory core is removed, it makes the system high in operational efficiency. Moreover, it is possible to add an extra memory core to the memory card, so it is convenient to replace the memory core.

According to an exemplary embodiment of the present invention, the flash memory card is high in operational efficiency and can conveniently replace the supplementary memory core.

The above-disclosed subject matter is to be considered illustrative, and not restrictive, and the appended claims are intended to cover all such modifications, enhancements, and other exemplary embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A flash memory card comprising:
a main memory core;
a removable supplementary memory core; and
a controller operating to control the main and supplementary memory cores,
wherein the supplementary memory core includes a plurality of memory cores and is replaceable in the flash memory card.

2. The flash memory card as set forth in claim 1, wherein each of the plurality of memory cores is the same or is different from each other in density.

3. The flash memory card as set forth in claim 1, wherein when the supplementary memory core is removed from the flash memory card, the controller activates the main memory core.

4. The flash memory card as set forth in claim 1, wherein when the supplementary memory core is connected to the flash memory card, the controller activates the main memory core and the supplemental memory core.

5. The flash memory card as set forth in claim 1, wherein the controller comprises:
a ROM storing firmware to manage the main memory core and to manage the plurality of memory cores in correspondence with respective densities of the main memory core and the plurality of memory cores;
a RAM storing firmware to manage the memory core having a density corresponding to firmware that is absent in the ROM; and
a central processing unit managing the main memory core and the plurality of memory cores by means of the firmware stored in the ROM and the RAM.

6. The flash memory card as set forth in claim 5, wherein the RAM is a static RAM.

7. The flash memory card as set forth in claim 5, wherein the central processing unit reads card identification information of the main memory core and confirms a density of the main memory core from the card identification information that has been read.

8. The flash memory card as set forth in claim 7, wherein the central processing unit selects firmware from the ROM in correspondence with the density of the main memory core.

9. The flash memory card as set forth in claim 8, wherein the central processing unit controls the main memory core by means of the selected firmware.

10. The flash memory card as set forth in claim 5, wherein the central processing unit reads card identification information of the plurality of memory cores and confirms the density of the plurality of memory cores by use of the card identification information that has been read.

11. The flash memory card as set forth in claim 10, wherein the central processing unit selects the firmware stored in the ROM in correspondence with each of the densities of the plurality of memory cores.

12. The flash memory card as set forth in claim 11, wherein the central processing unit controls the plurality of memory cores correspondingly by use of the selected firmware.

13. The flash memory card as set forth in claim 5, wherein if firmware for managing one or more memory cores is absent in the ROM, the central processing unit reads the firmware from one of the plurality of memory cores having a density correspondent with the firmware that is absent in the ROM.

14. The flash memory card as set forth in claim 13, wherein the central processing unit stores the firmware that has been read from the one of the plurality of memory cores into the RAM.

15. The flash memory card as set forth in claim 14, wherein the central processing unit selects the firmware stored in the RAM and controls corresponding memory cores by means of the selected firmware.
